(19) United States
(12) Patent Application Publication
(10) Pub. No.: US 2026/0110733 A1
(43) Pub. Date: Apr. 23, 2026

(54) POWER REGULATOR MONITORING CIRCUIT, POWER REGULATOR SYSTEM, AND METHOD OF MONITORING A POWER REGULATOR

(71) Applicant: Infineon Technologies AG, Neubiberg (DE)

(72) Inventors: Surya Kiran Venkata Rama Musunuri, Bengaluru (IN); Anmol Kaushik, Bangalore (IN)

(21) Appl. No.: 19/356,249

(22) Filed: Oct. 13, 2025

(30) Foreign Application Priority Data
Oct. 23, 2024 (DE) 102024130907.5

(51) Int. Cl. G01R 31/317; G01R 31/3183; G01R 31/319

(52) U.S. Cl. CPC G01R 31/31721; G01R 31/31724; G01R 31/31835; G01R 31/31924

(57) ABSTRACT

A power regulator monitoring circuit is provided. The power regulator monitoring circuit includes on a chip: a digital voltage monitor configured to take a sequence of measurements of an output voltage of a power regulator during a deterministic load increase and to provide the sequence of digital output voltage measurement values; a processing unit configured to receive and process the sequence of digital output voltage measurement values for determining at least one parameter of the power regulator that is indicative of a health state of the power regulator; and a memory storing instructions to be executed by the processing unit and/or by a further processor that is connected to the power regulator monitoring circuit, wherein the instructions stored in the memory are arranged to cause a deterministic load increase of the power regulator when the instructions are run on the processing unit and/or on the further processor.

### REFERENCE TO RELATED APPLICATION

This application claims priority to German Application number 102024130907.5, filed Oct. 23, 2024, the contents of which are hereby incorporated by reference in their entirety.

### TECHNICAL FIELD

Various embodiments relate generally to a power regulator monitoring circuit, to a power regulator system, and to a method of monitoring a power regulator.

### BACKGROUND

Modern System-on-Chips (SoCs) incorporate several accelerators, in addition to multiple processing cores and high-speed interfaces. These SoCs generate bursty load conditions to the power supply regulators in the system. Due to such aggressive variable load step stress, a power regulator performance may degrade over a period time. Any degradation of such regulator performance is especially important to detect for safety and reliability critical systems.

At present, power regulation issues may be detected by measuring voltage rails of the SoC using primary and secondary ADC (analog to digital converter) voltage monitors. These monitors detect a maximum droop of the voltage and generate an event/alarm once the droop crosses a pre-determined threshold. Alternate implementations use a change in current consumption or temperature profile of the system to indicate potential failure of power regulation.

### SUMMARY

A power regulator monitoring circuit is provided. The power regulator monitoring circuit includes on a chip: a digital voltage monitor configured to take a sequence of measurements of an output voltage of a power regulator during a deterministic load increase and to provide the sequence of digital output voltage measurement values; a processing unit configured to receive and process the sequence of digital output voltage measurement values for determining at least one parameter of the power regulator that is indicative of a health state of the power regulator; and a memory storing instructions to be executed by the processing unit and/or by a further processor that is connected to the power regulator monitoring circuit, wherein the instructions stored in the memory are arranged to cause a deterministic load increase of the power regulator when the instructions are run on the processing unit and/or on the further processor.

### BRIEF DESCRIPTION OF THE DRAWINGS

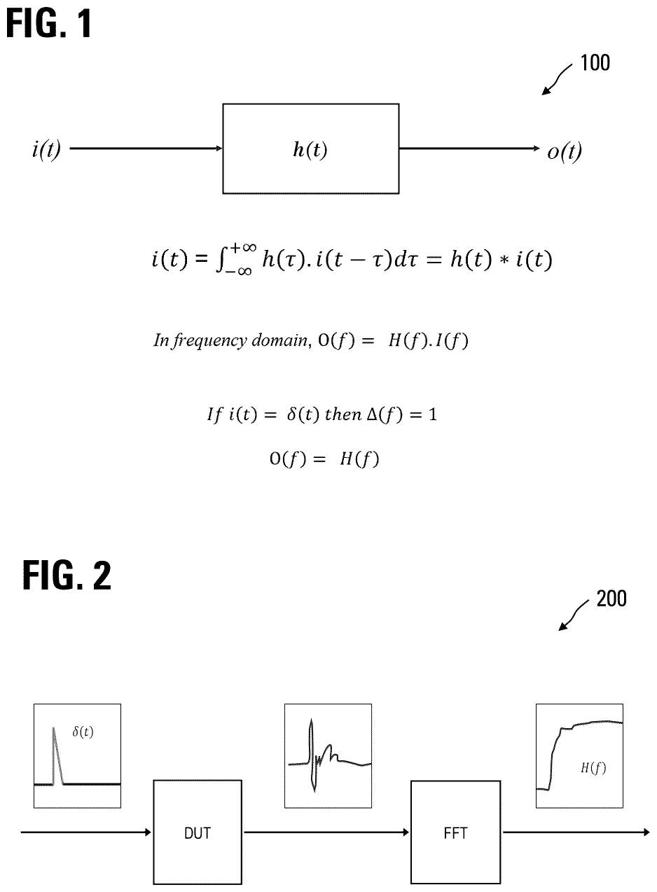

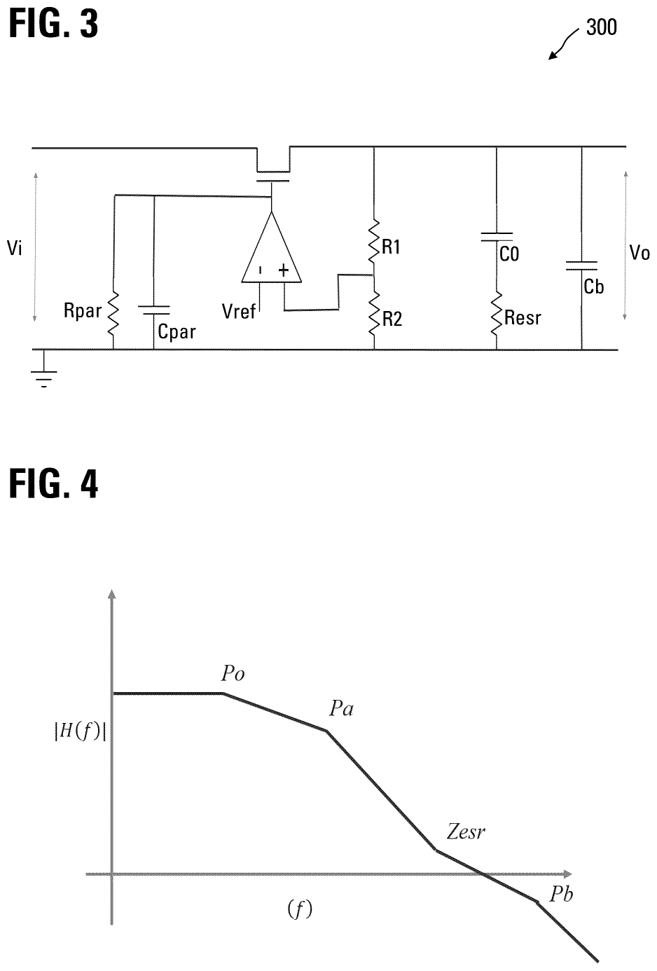

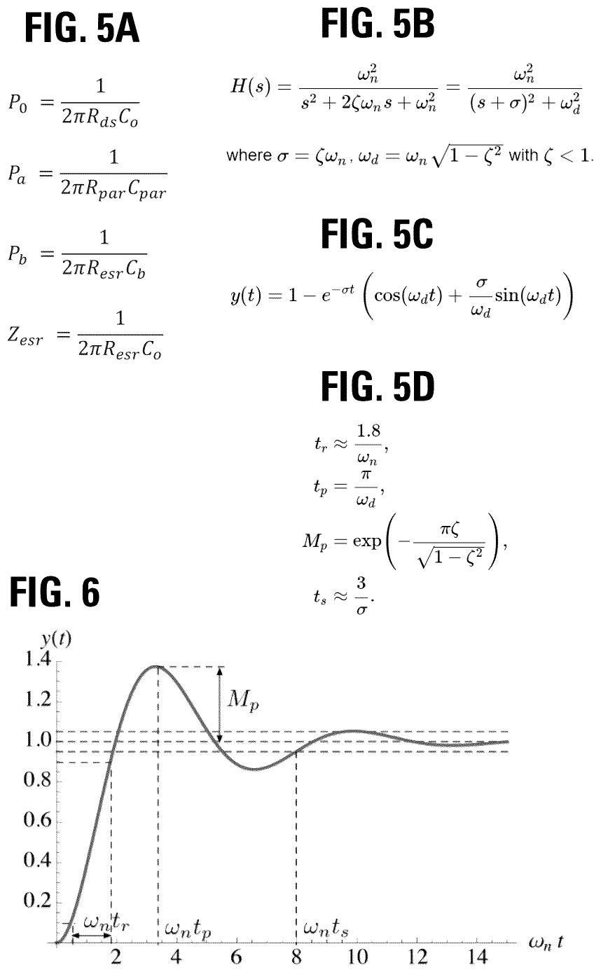

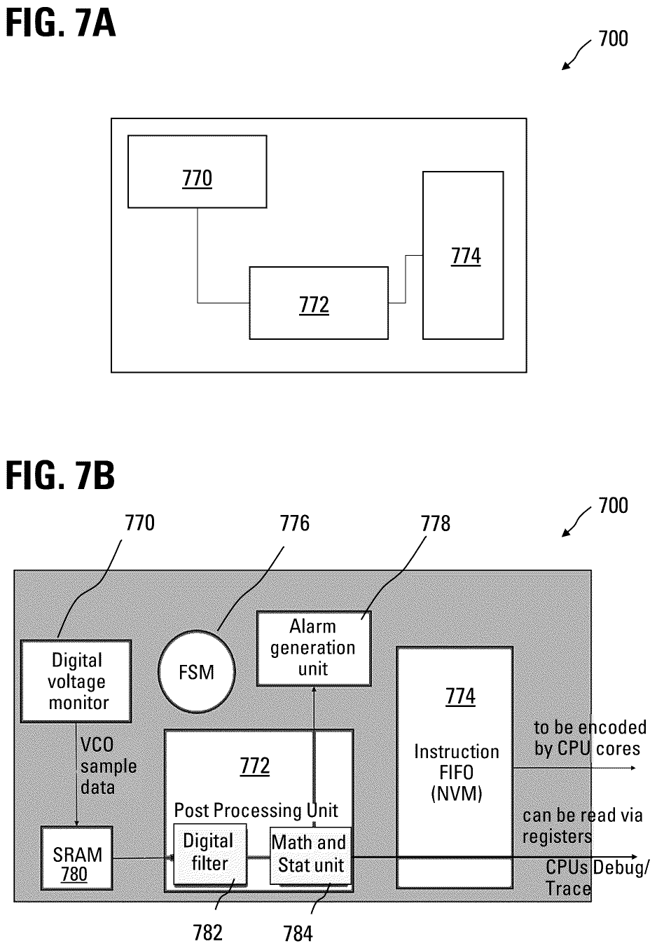

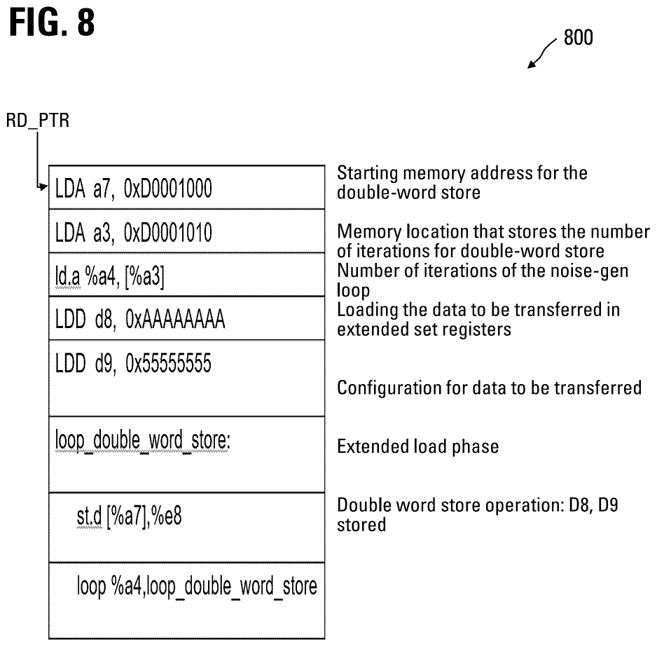

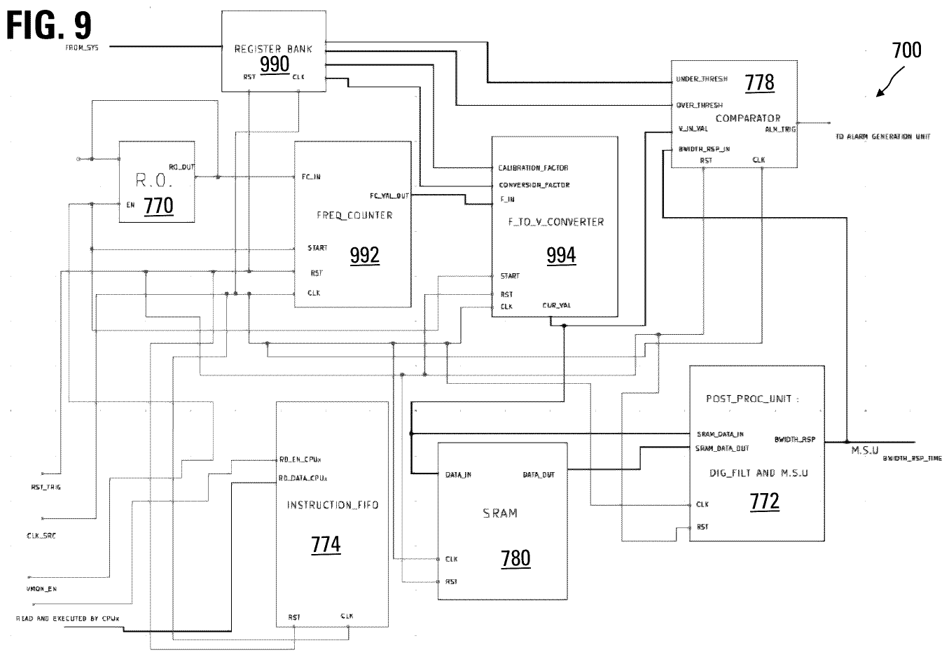

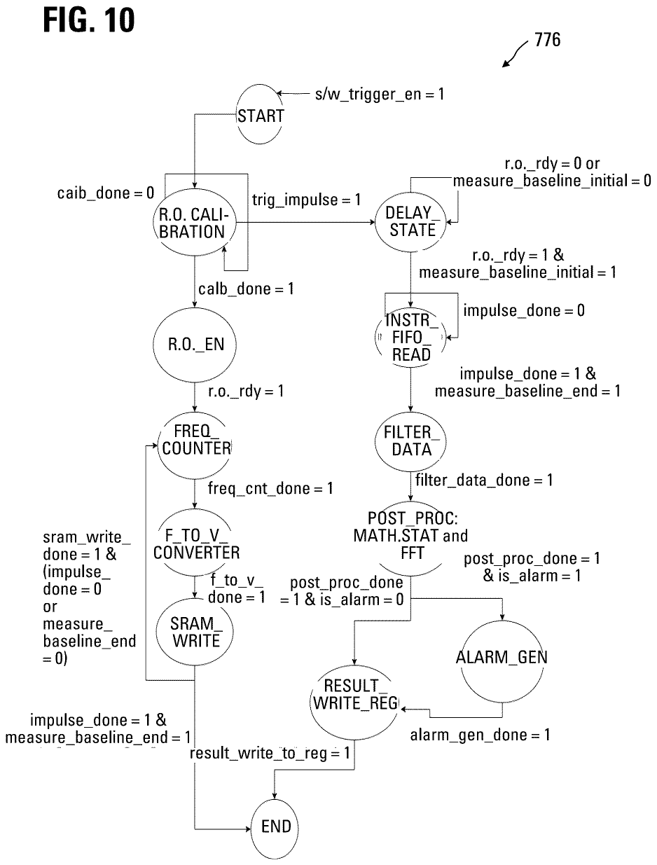

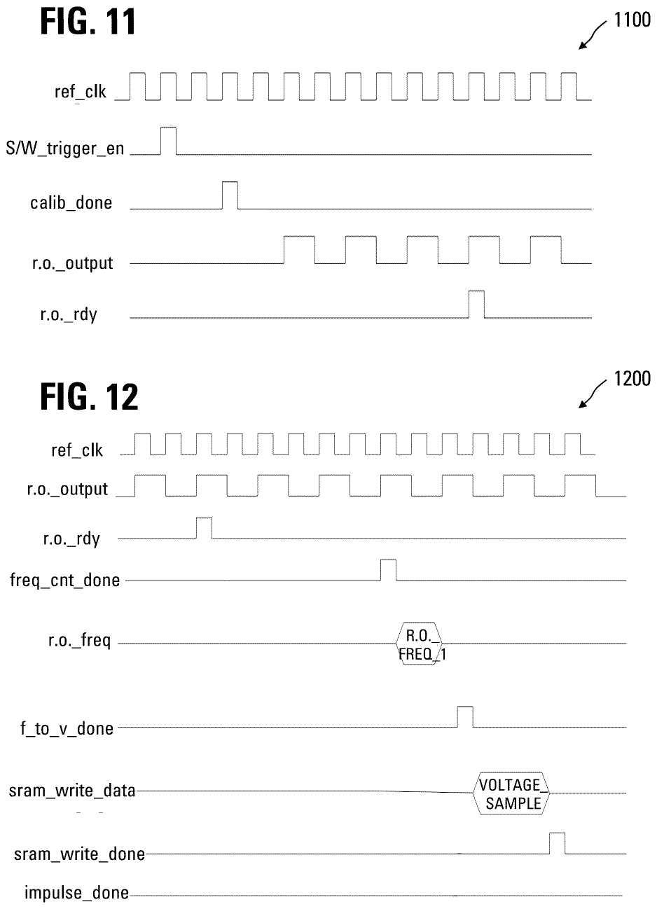

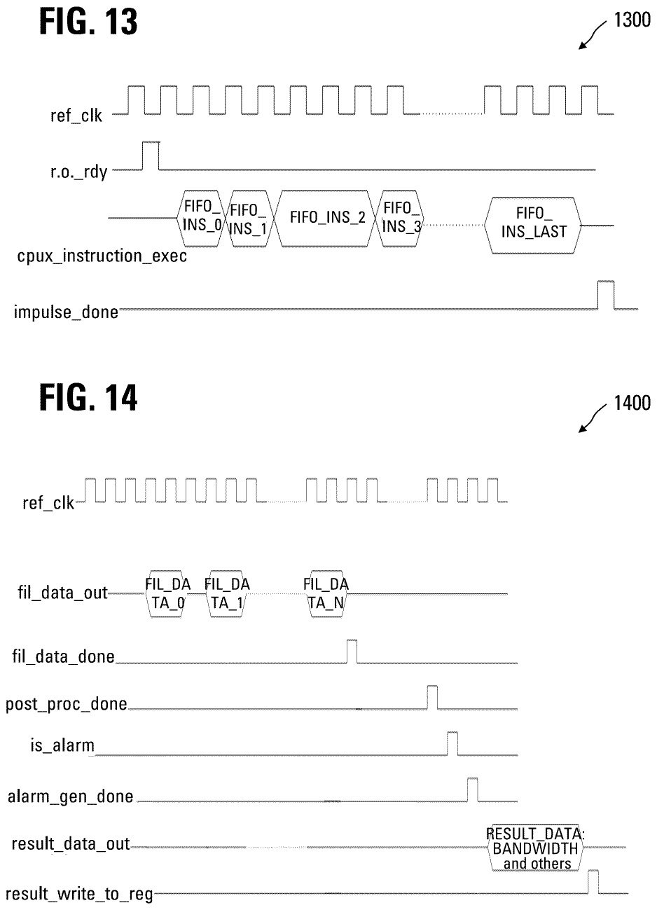

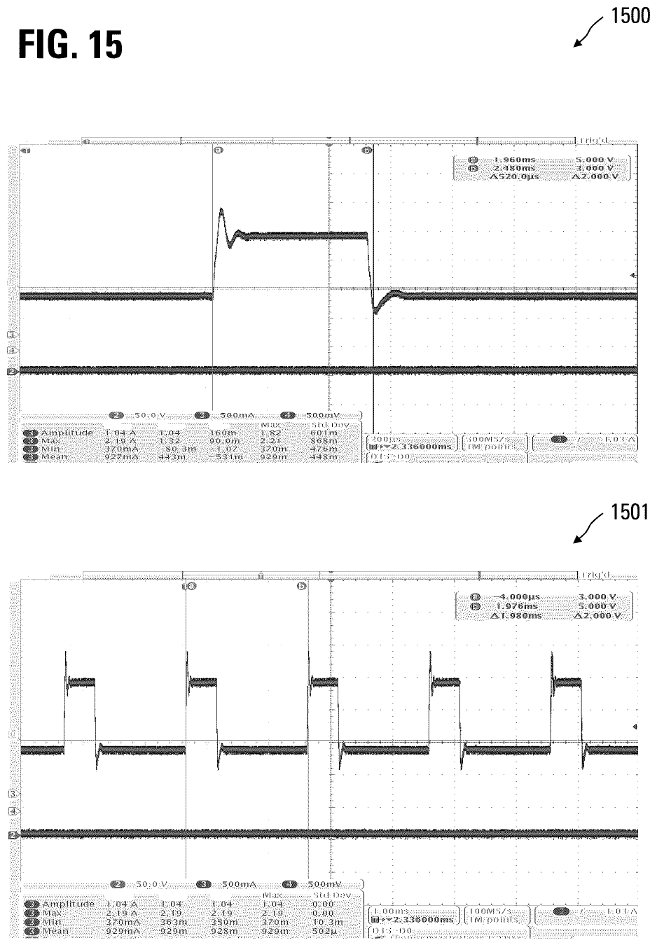

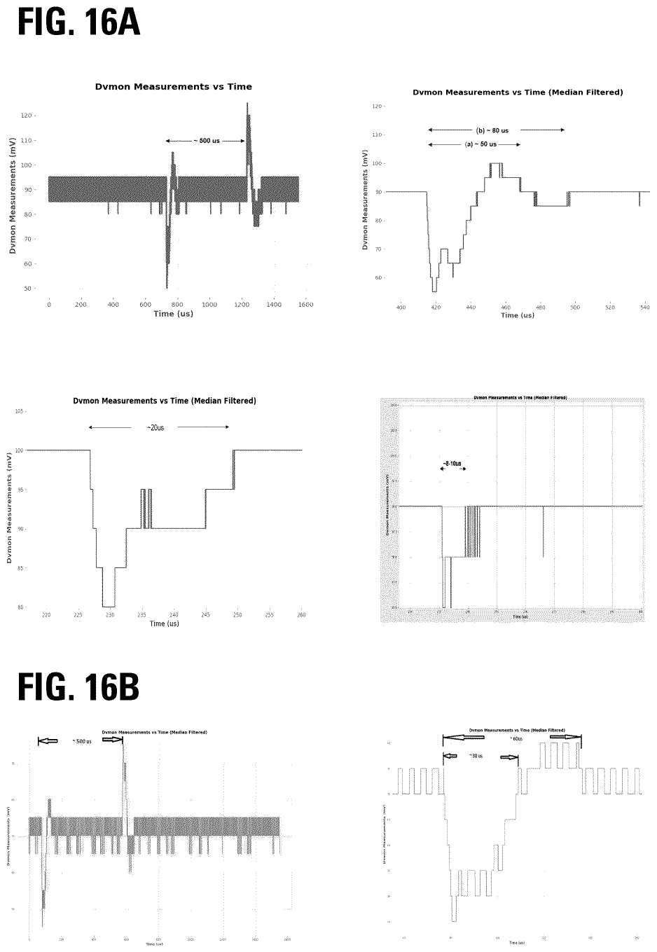

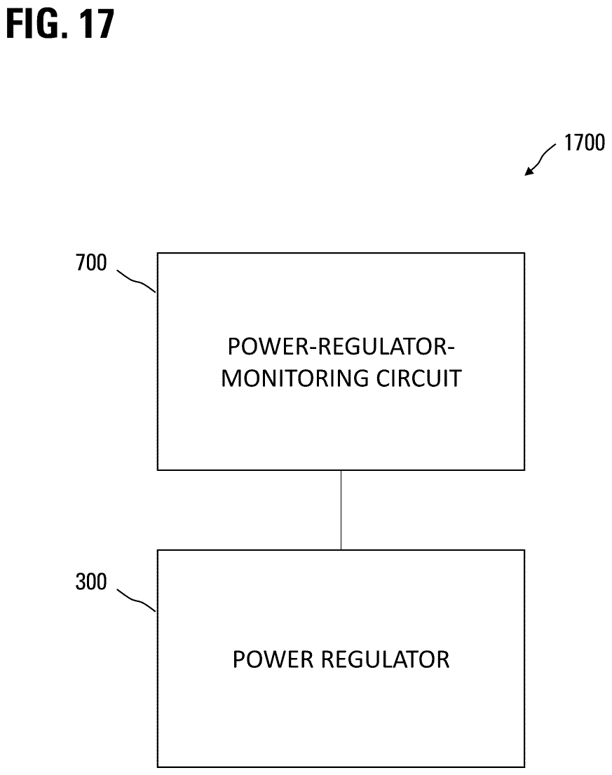

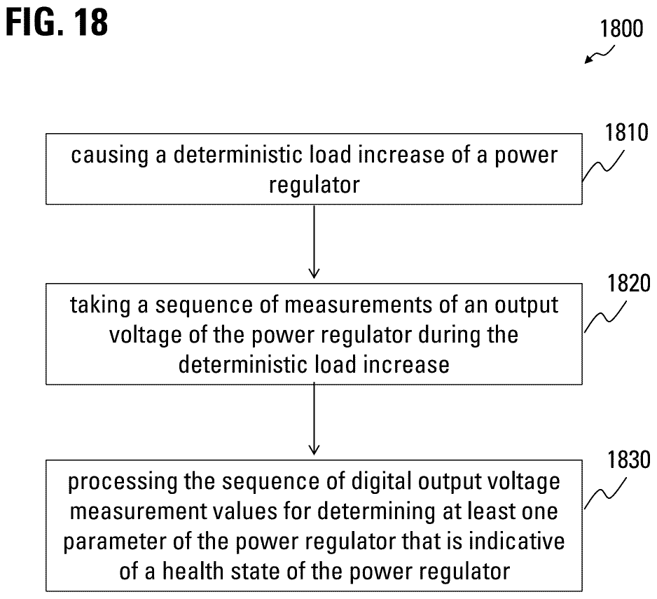

In the drawings, like reference characters generally refer to the same parts throughout the different views. The drawings are not necessarily to scale, emphasis instead generally being placed upon illustrating the principles of the disclosure. In the following description, various embodiments of the disclosure are described with reference to the following drawings, in which:
a. FIG. 1 shows a mathematical representation of an impulse function provided to a power regulator;
b. FIG. 2 illustrates a power regulator voltage response in time and frequency domains;
c. FIG. 3 shows an equivalent circuit of a power regulator implemented as a low dropout (LDO) regulator;
d. FIG. 4 shows a transfer function for the LDO regulator example of FIG. 3 as a function of frequency;
e. FIGS. 5A to 5D show several equations that are relevant in the context of transfer functions;
f. FIG. 6 shows a time-domain unit-step response for a transfer function;
g. each of FIGS. 7A and 7B schematically illustrates a power regulator monitoring circuit in accordance with various embodiments;
h. FIG. 8 shows an exemplary memory with stored instructions to be executed for generating a deterministic load increase in accordance with various embodiments;
i. FIG. 9 shows a lower-level block diagram of a power regulator monitoring circuit in accordance with various embodiments;
j. FIG. 10 schematically illustrates an exemplary state machine of a power regulator monitoring circuit in accordance with various embodiments;
k. FIG. 11 shows a timing diagram depicting an activation of a ring oscillator (R.O.) for use in a power regulator monitoring circuit in accordance with various embodiments;
l. FIG. 12 shows a timing diagram depicting one iteration of voltage sample acquisition in a power regulator monitoring circuit in accordance with various embodiments;
m. FIG. 13 schematically illustrates an impulse generation by stressful instruction execution in a power regulator monitoring circuit in accordance with various embodiments;
n. FIG. 14 illustrates a timing diagram that depicts the filtering of previously measured sample data, post processing, alarm generation and result provision in a power regulator monitoring circuit in accordance with various embodiments;
o. FIG. 15 illustrates a load-step duration (top) as provided by an exemplary power regulator monitoring circuit in accordance with various embodiments and illustrates a periodicity of the load step (bottom);
p. FIGS. 16A and 16B illustrate various measurements obtained during an operation of an exemplary power regulator monitoring circuit in accordance with various embodiments;
q. FIG. 17 schematically illustrates a power regulator monitoring system in accordance with various embodiments; and
r. FIG. 18 shows a flow diagram of a method of monitoring a power regulator in accordance with various embodiments.

### DESCRIPTION

The following detailed description refers to the accompanying drawings that show, by way of illustration, specific details and embodiments in which the disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, methods and devices are provided to detect a bandwidth (and/or implied transfer function) of power regulators using a self-test feature implemented in a power regulator monitoring circuit, for example as part of a System-on-Chip (SoC).

Degradation of power supply regulators is one of main root-causes for system failures. Various embodiments provide a novel way to test the health of power regulators in real-time. Most components used in this innovation are usually already available in modern SoCs. Therefore, there is no significant silicon area or board BOM (bill of materials) overhead for implementing these embodiments. Moreover, tracking the regulator health and detection of regulation failure pre-emptively helps achieving safety and security goals for automotive products.

Based on control theory, the power supply (implemented herein as a power regulator) may be modelled as a linear time invariant transfer function, h(t). It can be proven that an impulse function, when provided as input to the power regulator, generates an output equivalent to said transfer function. Mathematically, this may be represented by the formulas 100 reproduced in FIG. 1.

In an embedded electronic system, like for example a power regulator system of various embodiments that may be provided as an SoC, this impulse input may be realized by a fast load jump, which may excite the power regulator transfer function.

The generated voltage response of the power regulator may in various embodiments be analysed in both time and frequency domain, for example as illustrated in hybrid illustration 200 of FIG. 2 (with the power regulator indicated as “DUT” for “device under test”).

The Fast Fourier Transform (FFT) indicated in FIG. 2 may be realized in either hardware or software, and may be part of a power regulator monitoring circuit 700 in accordance with various embodiments.

Each of FIGS. 7A and 7B schematically illustrates a power regulator monitoring circuit 700 in accordance with various embodiments.

The power regulator monitoring circuit 700 includes, on a chip: a digital voltage monitor 770 configured to take a sequence of measurements of an output voltage of a power regulator during a deterministic load increase and to provide the sequence of digital output voltage measurement values; a processing unit 772 configured to receive and process the sequence of digital output voltage measurement values for determining at least one parameter of the power regulator that is indicative of a health state of the power regulator; and a memory 774 storing instructions to be executed by the processing unit 772 and/or by a further processor (not shown) that is connected to the power regulator monitoring circuit 700, wherein the instructions stored in the memory 774 are arranged to cause a deterministic load increase of the power regulator when the instructions are run on the processing unit 772 and/or on the further processor.

A corresponding power regulator system 1700, which includes a power regulator 300 and the power regulator monitoring circuit 700, is schematically illustrated in FIG. 17.

The processing unit 772 may for example include one or more digital filters 782 configured to filter out noise in the sequence of digital output voltage measurement values, and one or more further units 784 for executing mathematical operations and/or performing statistics on the filtered sequence of digital output voltage measurement values.

The memory 774 may for example be configured to store the instructions for sequential execution, for example in a non-volatile memory (NVM), for example in a register configured for first-in-first-out (FIFO) processing of the instructions.

In various embodiments, despite the stored instructions being executed sequentially, any individual instruction of the stored instructions may optionally be provided to a plurality of processor cores (of an external processor, for example a CPU, as indicated in FIG. 7B, or for example by the processing unit 772) for parallel execution, for example the instructions that are configured to cause the load increase (and corresponding voltage drop).

In an exemplary embodiment of the power regulator system 1700, the power regulator 300 may be implemented as an LDO (Low dropout) regulator. A corresponding equivalent circuit is shown in FIG. 3.

Since an LDO regulator, e. g., its components and functions, is/are in principle known to a person skilled in the art, a detailed description is omitted, the focus being on aspects that relate to an interaction with the power regulator monitoring circuit 700 of various embodiments.

It may be noted, however, that in various embodiments, the power regulator monitoring circuit 700 may not only be used for monitoring a state of the power regulator 300 and for optionally raising an alarm in case of parameters that are beyond predefined thresholds, but equivalent circuit parameters of the power regulator 300 may additionally be compared to reference equivalent circuit parameters of the power regulator.

The power regulator 300 may include a feedback loop, and if a comparison of the determined parameters with the reference equivalent circuit parameters indicates that the determined equivalent circuit parameters differ from the reference equivalent circuit parameters of the power regulator by a correctable amount, update feedback values may be provided to the feedback loop based on the determined equivalent circuit parameters. This means that even a fixing of the power regulator 300, up to a certain grade of severety, may be made possible by the power regulator monitoring circuit 700.

An impulse load change on the power regulator 300 (the LDO regulator) would create a voltage droop transient followed by a recovery period.

By analysing a time domain voltage transient response, a recovery time may be calculated. This recovery time is directly related to an overall closed loop bandwidth of the power regulator 300, or the power regulator system 1700, respectively.

A fast fourier transform (FFT) of a transient voltage response may lead to a transfer function |H(f)| versus frequency, which, for the LDO regulator example, may look as shown in FIG. 4.

−20 dB/dec and −40 dB/dec roll-off points in the FFT |H(f)| of the transient voltage response of FIG. 4 indicate corresponding poles (P0, Pa, Pb) and zeroes (Zesr) of the LDO power regulator. Numerically, the poles (P0, Pa, Pb) and zeroes (Zesr) can be denoted as indicated in the equations reproduced in FIG. 5A.

By computing above pole (P0, Pa, Pb) and zero (Zesr) values from the FFT output |H(f)|, the equivalent circuit parameters of the power regulator 300 may be derived. The absolute and relative values of these parameters may be indicative of an overall health of the power regulator 300.

In various embodiments, a similar approach may be used for other types of power regulator, for example for a DC-DC buck regulator, for a boost regulator, or for a buck-boost regulator, and other power regulators.

A similar approach may in various embodiments be used to study the bandwidth of the power regulator 300 using a unit-step response.

A generic second order transfer function H(s) would be of the form shown in the equation reproduced in FIG. 5B.

A unit-step response y(t) for the transfer function H(s) would be of the form indicated in FIG. 5C.

What this unit-step response y(t) looks like in time-domain is shown graphically in FIG. 6.

With an assumption that a damping ratio ζ is around 0.5, time domain parameters like a rise time tᵣ (the time to rise from 10% to 90% of final value, to which the y-scale is normalized), a peak time tₚ (time to reach the first peak value), a maximum overshoot Mₚ, (a percentage by which the maximum value overshoots over the final value), and a settling time tₛ (a time to reach a point where the voltage stays within 5% deviation from the final value) may be derived using the equations reproduced in FIG. 5D.

Thus, by using a unit-step load change and measuring the voltage transient of the power regulator 300, a natural frequency ωₙ, damped natural frequency ω_{d}, as well as an approximate overall bandwidth B≈Wₙ (1−2ζ²)^{0.5} of the power regulator 300) may be determined.

In the following, an exemplary technical implementation in accordance with various embodiments is described with reference to FIGS. 7B to 16.

The power regulator monitoring circuit 700 implements an on-chip test logic that evaluates the bandwidth and integrity of an SoC's power regulator 300, configured as a DC power supply source.

The logic may be centred around the use of a digital voltage monitor 770 in conjunction with synchronized stress generation on the SoC's CPU cores. An evaluation may start with a trigger of the digital voltage monitor 770 post self-calibration and configuration.

Following this, the SoC's CPU core(s) may synchronously execute a series of instructions placed in a segment of the (non-volatile) memory 774. This is intended to cause a significant dynamic voltage droop event on the core supply voltage rail. This event, and the subsequent recovery from it, may be captured by the digital voltage monitor 770.

The power regulator monitoring circuit 700 may in various embodiments include a further memory 780, for example a volatile memory, for example an SRAM, and the voltage measurement samples, e. g. a stream of voltage values provided by the digital voltage monitor 770, may be stored in the further memory 780.

The processing unit 772 (also referred to as post-processing unit or as post-process logic) may include one or more digital filters 782, for example a digital moving average filter, and one or more further units 784 configured to perform mathematical and/or statistical operations. The processing unit 772 may filter the stream of voltage values and may measure the time taken to recover from the induced VDD droop event. Time of recovery from the droop event (bandwidth) and noise in the VDD signal may provide input to an alarm generation unit (AGU 778) that may be part of the power regulator monitoring circuit 700. If the stream of voltage values indicates voltage overshoots and/or undershoots with respect to preconfigured thresholds, the alarm generation unit 778 may raise alarm events signifying that the threshold(s) has/have been exceeded.

The digital voltage monitor 770 may in various embodiments be responsible for providing raw voltage sample data during the execution of the load-jump/impulse-response trigger.

In various embodiments, the digital voltage monitor 770 may be configured as a ring oscillator (R.O.) based monitor.

The ring oscillator based monitor is illustrated in FIG. 9 as a lower-level block diagram. An n-stage ring oscillator (R.O.) is implemented, an output frequency of which is affected by a change in supply voltage due to a change in delay time of each inverter stage. When deciding on the number of stages of the ring oscillator, a required granularity, with which the voltage variations need to be measured with respect to time (nano-second scale, micro-second scale etc.) may be taken into consideration. This may also depend on a width of the load-jump/impulse-response trigger. Also, an enable (EN) signal may be provided to maintain two operation modes: oscillating and non-oscillating (R.O.). An output signal of the R.O. may be fed to a frequency counter 992 (FREQ_COUNTER). The frequency counter may calculate the frequency of the R.O. while using a clock-source as a time-base. The frequency value may then be fed to a converter block 994 (F_TO_V_CONVERTER). The converter block 994 uses scalar factors (adjusted during calibration) to convert the frequency values to digital voltage samples, e. g., a stream of sampled voltage values.

The R.O. based approach may have a low power consumption and low area requirements. On the other hand, the R.O. based approach may require careful calibration and possibly complex methods to convert frequency values to voltage samples.

In various embodiments, the digital voltage monitor 770 may be configured as an Analog-to-Digital-Converter (ADC) based monitor.

An ADC based voltage monitoring may be performed by embedding a monitoring ADC (e.g. SAR based). A resolution of the ADC needs to be appropriately decided in addition to the response time. These parameters should be adequately able to capture the voltage fluctuation during the load event. This approach may possibly make use of a reference current for calibration and complex calibration. Additionally, due to area limitations, the ADCs may possibly need to be placed at limited locations and might miss out on hot spots.

The memory 774 storing instructions to be executed by the processing unit and/or by a further processor that may be connected to the power regulator monitoring circuit may be considered as forming part of a load-impulse circuit.

The load-impulse circuit may be configured to generate a significant dynamic voltage droop event (a load increase) on a voltage rail that is under test. The event is deterministic in nature to ensure system consistency and accuracy. This event is supposed to trigger an impulse-response from the power supply 300 network that is under evaluation. This may for example be implemented as follows:

I. Synchronized execution of stressful instructions from an instruction FIFO (INSTRUCTION_FIFO). This approach has been highlighted in the implementation as described above. The SoC's CPU cores may be configured to synchronously execute a series of instructions placed in a non-volatile memory-based FIFO. The sequence must be designed using instructions that cause a significant dynamic load-jump by stressing CPU and bus logic. Synchronous execution of the instruction series may provide a clean and major load-spike that is easily differentiable from noise and may generate an appropriate response from the power supply.

FIG. 8 illustrates an example sequence 800 for instructions that are configured to generate a load by instructing a processor (this may be the processing unit 772 and/or the processor that may be external to the power regulator monitoring circuit 700, but part of the power regulator system 1700) to (e. g., repeatedly) execute a double word store process.

II. Known-algorithmic accelerator load. Alternatively or additionally, a significant voltage droop event may in various embodiments be created by forcing an algorithmic accelerator/co-processor to perform stressful calculations such as SHA (hashing engine), AES base cryptography (security core), Kalman filter (parallel processing accelerator), or the like. The instructions that trigger such calculations may be placed in the instruction FIFO in a similar way as depicted in FIG. 8.

III. Resistive-load circuit. For voltage rails where a load-jump cannot be created by processor (e. g., CPU) based instruction execution, a resistive load circuit may be used. For such a resistive-load inverter, an enhancement type nMOS transistor may act as a driver device.

It may be noted that a hardware sequencer may be used for triggering the power jump, since a software implementation may not be fast enough. The hardware trigger may for example include triggering the processor cores to run in parallel using the specific instructions from the instruction FIFO which are selected to create a load jump. It may be irrelevant if they do not do anything useful, since the only goal is to create the load jump.

The alarm generation unit 778 may include comparators. Digital multi-bit comparators may be used to evaluate whether the latest voltage sample received is within the specified range. Additionally, another comparator may be used to check whether the calculated power supply bandwidth is within an acceptable range. Threshold ranges may be provided by the user via registers 990. In case of a violation (e.g., a measured voltage exceeding the threshold), an appropriate alarm signal may be generated.

The (post-)processing unit 772 may form the computational hub of the circuit that operates upon the voltage sample data received from the digital voltage monitor 770. The processing unit 772 may include a digital filter unit 782 configured to filter the raw noisy data and to provide a clean input to the math and statistical unit (M.S.U) 784. The M.S.U 784 may be responsible for calculating a time required by the power regulator 300 to adequately recover from the impulse/load-jump and return to a stable level.

Digital Filter 782: Data captured by the digital voltage monitor 770 may have the potential to be noisy. Therefore, selection of an appropriate digital filter is key to accurate measurements. Numerous suitable filter options are available, some of which include: Spike filters, Type filters (min gate count FIR Low pass filter), and Performance FIR filters.

Math and statistic unit 784: This part of the (post-)processing unit 772 may be key to the calculation of the power regulator bandwidth. Filtered data may be taken as an input. The point at which a significant statistical deviation with respect to a stable baseline is observed is automatically detected as the start of the voltage droop event. Time-to-recovery is calculated by evaluating the time taken to return to the stable baseline observed initially. Such measurements require statistical observations such as the calculation of mean, standard deviation etc. An FFT engine may also be part of the math and statistic unit 784. The FFT engine is a dedicated unit that takes in the time domain measurements of voltage samples and provides the frequency-domain relevant data as described above.

In various embodiments, the power regulator monitoring circuit 700 may further include a finite state machine (FSM) 776 that may assume a number of different voltage monitoring states and impulse/load-step generation and bandwidth calculation states.

FIG. 10 illustrates an implementation of the state machine 776, and specifically the following states and how they relate:

### Voltage Monitoring States:

START: This is the system's initial state which becomes active when an enable trigger is received via application S/W. This trigger is basically a sequence of register writes that enable the self-test. A transition to enable the ring oscillator is performed to escape the state.
R.O_CALIBRATION: As mentioned above, the R.O. based approach may need proper calibration to achieve accurate results. This state represents the calibration process which yields scalar calibration factors that help in enhancing the accuracy of the R.O. based measurement process. Once the calibration process is finished (calib_done=1), next state is activated.
R.O. EN: The ring oscillator gets activated in this state. Once the ring oscillator output is stable (r.o._rdy=1), next state is triggered.
FREQ_COUNTER: This state is responsible for calculating the frequency of the ring oscillator. Once freq_cnt_done=1, the R.O. frequency sample gets converted to corresponding voltage data in the next stage.
F_TO_V_CONVERTOR: Frequency sample value from the previous state gets converted to voltage data based on a few scalar parameters that have been written into SFRs post calibration. A state transition is achieved when the signal conversion is finished (f_to_v_done=1).
SRAM_WRITE: Voltage data are captured over time during the impulse generation/load-step. These data are then written into an SRAM module. Once a voltage sample is written into SRAM (sram_write_done=1), acquisition of the next voltage sample continues till the impulse generation (impulse_done=1) and the baseline measurements (measure_baseline_end=1) are finished. Baseline measurements refer to the few extra samples captured after the impulse generation to obtain data that can be correlated to voltage droop recovery. Once the impulse and extra sample measurements are finished, a transition to the END state is performed for this half of the implementation.

### Impulse/Load-Step Generation and Bandwidth Calculation States

DELAY_STATE: Once impulse generation is enabled (trig_impulse=1), this part of the logic waits till the R.O. output is stable (r.o._rdy=1) and a few samples have been measured to establish some baseline data (measure_baseline_initial=1).
INSTR_FIFO_READ: This is the core part of the impulse generation. All CPU cores of the SoC start executing stressful instructions placed in a FIFO synchronously (impulse_done=0). This leads to a significant current jump.

When all instructions have been read out by the CPUs (impulse_done=1) and the measurement process is finished (measure_baseline_end=1), post processing of the captured data is started.
FILTER_DATA: Noisy data from the data acquisition stage are filtered with use of appropriate digital filters as mentioned above (filter_data_done=1).
POST_PROC, ALARM_GEN and RESULT_WRITE_REG: This stage is responsible for the mathematical functions and FFT implementations that result in the output parameters including bandwidth of the power supply circuit and other parameters from the frequency domain. If the calculated values exceed pre-set thresholds, an alarm signal is generated (post_proc_done=1 & is_alarm=1). Else, the values are written to output registers directly (post_proc_done=1 & is_alarm=0). Following this, END state is reached.
END: Final stage of the process. Here, the teardown is performed: Voltage monitoring circuit, impulse generation and post processing units are disabled.

FIGS. 11 to 14 illustrate, in respective timing diagrams 1100, 1200, 1300, and 1400, in relation to a reference clock signal, the timing of the states described with reference to FIG. 9. FIG. 11 illustrates a ring oscillator output signal, more specifically timing of states related to an activation of the ring oscillator. FIG. 12 illustrates a timing of states related to voltage monitoring, more precisely one iteration of voltage sample acquisition. FIG. 13 illustrates an impulse generation, more specifically an impulse generation by instructing to execute a stressful process. FIG. 14 illustrates timing of filter data and post-processing, more specifically, the filtering of previously measured sample data, post processing via the math and stat unit and finally, alarm generation and result provision.

FIGS. 15, 16A and 16B illustrate results from example tests that have been performed using an exemplary power regulator system 1700 with a power regulator monitoring circuit 700 essentially as described above, with the difference that post-processing has been performed off-chip in an external desktop computer.

For the example test, the ring oscillator based power regulator monitor circuit 700 approach was tested by emulating the power regulator system 1700 using modules available on the Aurix 3G device, a stress-test software and python-based scripts for post-processing (host PC).

As the digital voltage monitor 770, a DVMON module was used, which is a ring oscillator based on-chip voltage monitor that is able to generate voltage measurement samples at a nano-seconds scale.

Instruction FIFO: An embedded stress-test known as NoiseFramework was used to generate the synchronized load-jump.

NoiseFramework is a multi-core test framework that triggers six CPU cores of the A3G device to synchronously execute a sequence of stressful instructions. The framework was configured to generate a load-step with the following specifications:

| Information | Specifications | |
|---|---|---|
| Target Content | NoiseFrameworkV2AggAgg | |
| Load-Step Duration | 500 | μs |
| Iteration period | 1.966 | ms |

Voltage data acquisition: The DVMON voltage sample values were dumped to an on-chip RAM memory 780 using the MCDS trace module of TC4Dx. The specifications of the trace capture are specified below:

| Information | Specifications |
|---|---|
| Device | Aurix 3G |
| DVMON # | DVMON 0 |
| Trace Mode | ONCHIP_RAM |
| Trace Buffer | LMU0 (512 kB) |

A python script executing on a host PC configures DVMON and triggers trace.

Post-Processing unit: A python script executing on a host PC is used for filtering the DVMON sample data using median filter (various kernel sizes used) and then plotting the filtered data.

Result details and waveforms: The aforementioned setup was used to perform experiments and establish the flow in a post-silicon environment.

FIG. 15 illustrates, in the top panel 1500, a duration of the load-step generated by the NoiseFramework. As can be observed, the CPU cores are idle until they receive a timer based trigger. Upon receiving the trigger, six CPU cores of the device execute the stress function. This load-step lasts for around 520 μs. After this, the cores go back to idle condition and wait for the next trigger.

FIG. 15 illustrates further, in the bottom panel 1501, a load-step periodicity: The load-step is repeated after every 1.98 ms.

FIG. 16A illustrates Dvmon sample data plots vs time that were captured for the following three scenarios:
Case 1: ROVACS with DC Power Supply E3633A (VDD: Single Channel, VEXT+1V8: Dual Channel) EVRCOFF
Case 2: ROVACS with DC Power Supply E3633A (VDD: Single Channel, VEXT+1V8: Dual Channel) EVRCON
Case 3: Eval Board (Single DC Power Adapter, PMIC)

VDD recovery timings are marked on the graphs. These are approximate values.

In FIG. 16A, the top left panel illustrates Case 1 and shows the unfiltered data capture that covers the load-jump event. A voltage droop event is observed at around the 720-740 μs mark, and the sequence lasts for about ˜500 μs. This matches the stress content parameters as described above.

In FIG. 16A, the top right panel shows a zoomed-in plot of the VDD droop region and the subsequent recovery of the top left panel (Median Filter, Kernel Size 81). The VDD droop occurs at ˜418 μs mark and it continues to go down and recovers up-to (a) (˜50 μs). But even at (a), the supply voltage is slightly unstable, it takes around ˜80 μs to reach a stable value.

In FIG. 16A, the bottom left panel illustrates Case 2 with a zoomed-in plot: ROVACS with DC Power Supply E3633A (VDD: Single Channel, VEXT+1V8: Dual Channel) EVRCON

This case is with the embedded voltage regulator enabled. This should result in a faster response time and return to a stable state. In the zoomed-in plot, it can be observed that the VDD supply recovered at a faster rate of ˜20 μs, as expected.

In FIG. 16A, the bottom right panel illustrates Case 3. It is observed that the response time is even lower with a PMIC where it is around ˜10 ns.

In summary, this method is able to distinguish between three different power supply regulation bandwidth/response times.

FIG. 16B illustrates results of a test of a power regulator failure scenario.

To mimic a close to unstable regulator, two test methods may be used.

One method reduces the total bulk capacitance of the buck regulator output domain to mimic loss of regulator or unstable control behaviour.

Another method reduces the switching frequency of a buck regulator to mimic reduced bandwidth operation. This method may also be used to check the scalability of bandwidth measurement (by either increasing or reducing the switching frequency).

Test results from this method are shown below.

To emulate a power supply failure, the following setup was used:
Reduction of buck switching frequency and along with enabling the frequency spread feature.
Switching frequency reduced to 0.1956 MHz from default of 0.8 MHz, lowest supported officially is 0.4 MHz).

$$Switching Factor = 0 \times 1 FF , Spread = 0 \times 7 F .$$

A median filter is used to smooth out the supply voltage noise.

FIG. 16B illustrates, in the left panel, the high-level behaviour of the measured voltage (500 μs load step, median filtered with kernel size=81), and in the right panel, which is zoomed in at the droop region of FIG. 16B (left), and shows the reduced EVRC switching frequency with spread. It is medial filtered with a kernel size=81).

FIG. 18 shows a flow diagram 1800 of a method of monitoring a power regulator in accordance with various embodiments.

The method includes causing a deterministic load increase of the power regulator (1810); taking a sequence of measurements of an output voltage of the power regulator during the deterministic load increase (1820); and processing the sequence of digital output voltage measurement values for determining at least one parameter of the power regulator that is indicative of a health state of the power regulator (1830).

Various examples will be illustrated in the following:

Example 1 is a power regulator monitoring circuit. The power regulator monitoring circuit includes on a chip: a digital voltage monitor configured to take a sequence of measurements of an output voltage of a power regulator during a deterministic load increase and to provide the sequence of digital output voltage measurement values; a processing unit configured to receive and process the sequence of digital output voltage measurement values for determining at least one parameter of the power regulator that is indicative of a health state of the power regulator; and a memory storing instructions to be executed by the processing unit and/or by a further processor that is connected to the power regulator monitoring circuit, wherein the instructions stored in the memory are arranged to cause a deterministic load increase of the power regulator when the instructions are run on the processing unit and/or on the further processor.

In Example 2, the subject-matter of Example 1 may optionally include that the processing unit and/or the further processor, respectively, includes a plurality of processor cores; and that the instructions are configured to be run on the plurality of cores in parallel to cause the deterministic load increase.

In Example 3, the subject-matter of Example 1 or 2 may optionally further include a further memory connected between the voltage monitor and the processing unit.

In Example 4, the subject-matter of any of Examples 1 to 3 may optionally include that the further memory includes or consists of a volatile memory, for example an SRAM.

In Example 5, the subject-matter of any of Examples 1 to 4 may optionally further include a hardware finite state machine (FSM) to control the digital voltage monitor and to trigger the deterministic load increase

In Example 6, the subject-matter of any of Examples 1 to 5 may optionally be configured to compare the determined at least one parameter to at least one reference parameter and to execute an action based on the result of the comparison; wherein, optionally, the action includes raising an alarm if the determined at least one parameter deviates by more than a predefined amount or percentage from the at least one reference parameter.

In Example 7, the subject-matter of any of Examples 1 to 6 may optionally include that the at least one parameter includes at least one of a group of parameters, the group including or consisting of: a bandwidth of the power regulator; an equivalent circuit parameter of the power regulator; a time of recovery from a voltage droop event caused by the deterministic load increase; and noise in the voltage signal.

In Example 8, the subject-matter of any of Examples 1 to 7 may optionally include that the processing further includes a Fourier transform for determining a transfer function.

In Example 9, the subject-matter of Example 8 may optionally include that the processing further includes determining, from the transfer function, equivalent circuit parameters of the power regulator.

In Example 10, the subject-matter of Example 9 may optionally include that the processing further includes comparing the equivalent circuit parameters of the power regulator to reference equivalent circuit parameters of the power regulator; that the power regulator further includes a feedback loop; and that the power regulator monitoring circuit is further configured, if a result of the comparison indicates that the determined equivalent circuit parameters differ from the reference equivalent circuit parameters of the power regulator by a correctable amount, to update feedback values to the feedback loop based on the determined equivalent circuit parameters.

In Example 11, the subject-matter of any of Examples 5 to 10 may optionally include that the finite state machine (FSM) is further configured to register, synchronize and update states of the power regulator monitoring circuit using a common clock signal.

In Example 12, the subject-matter of any of Examples 1 to 11 may optionally include that the processing unit further includes a filter configured to filter out noise from the sequence of digital output voltage measurement values.

Example 13 is a power regulator system. The power regulator system includes a power regulator; and the power regulator monitoring circuit of any of Examples 1 to 12.

In Example 14, the subject-matter of Example 13 may optionally include that the power regulator is configured as one of a group of power regulators, the group including or consisting of: a Low Drop-Out (LDO) power regulator; a DC-DC buck power regulator; a DC-DC boost power regulator; and a DC-DC buck-boost power regulator.

In Example 15, the subject-matter of Example 13 or 14 may optionally be configured as a System-on-Chip (SoC).

Example 16 is a method of monitoring a power regulator. The method includes causing a deterministic load increase of the power regulator; taking a sequence of measurements of an output voltage of the power regulator during the deterministic load increase; and processing the sequence of digital output voltage measurement values for determining at least one parameter of the power regulator that is indicative of a health state of the power regulator.

In Example 17, the subject-matter of Example 16 may optionally include that the causing the load increase and the taking the sequence of measurements of the output voltage are synchronized through a common clock signal.

In Example 18, the subject-matter of Example 16 or 17 may optionally include that the processing unit and/or a further processor, respectively, includes a plurality of processor cores; and that the causing the deterministic load increase includes running instructions on the plurality of cores in parallel.

In Example 19, the subject-matter of any of Examples 16 to 18 may optionally further include that the controlling the digital voltage monitor and a triggering the deterministic load increase is performed by a hardware finite state machine (FSM).

In Example 20, the subject-matter of any of Examples 16 to 19 may optionally be configured to compare the determined at least one parameter to at least one reference parameter and to execute an action based on the result of the comparison; wherein, optionally, the action includes raising an alarm if the determined at least one parameter deviates by more than a predefined amount or percentage from the at least one reference parameter.

In Example 21, the subject-matter of any of Examples 16 to 20 may optionally include that the at least one parameter includes at least one of a group of parameters, the group including or consisting of: a bandwidth of the power regulator; an equivalent circuit parameter of the power regulator; a time of recovery from a voltage droop event caused by the deterministic load increase; and noise in the voltage signal.

In Example 22, the subject-matter of any of Examples 16 to 21 may optionally include that the processing further includes a Fourier transform for determining a transfer function.

In Example 23, the subject-matter of Example 22 may optionally include that the processing further includes determining, from the transfer function, equivalent circuit parameters of the power regulator.

In Example 24, the subject-matter of Example 239 may optionally include that the processing further includes comparing the equivalent circuit parameters of the power regulator to reference equivalent circuit parameters of the power regulator; that the power regulator further includes a feedback loop; and that the power regulator monitoring circuit is further configured, if a result of the comparison indicates that the determined equivalent circuit parameters differ from the reference equivalent circuit parameters of the power regulator by a correctable amount, to update feedback values to the feedback loop based on the determined equivalent circuit parameters.

In Example 25, the subject-matter of any of Examples 19 to 24 may optionally include that the finite state machine (FSM) is further configured to register, synchronize and update states of the power regulator monitoring circuit using a common clock signal.

In Example 26, the subject-matter of any of Examples 16 to 26 may optionally include that the processing unit further includes a filter configured to filter out noise from the sequence of digital output voltage measurement values.

Example 27 is a method of operating a power regulator system including a power regulator. The method may include providing power using the power regulator; and monitoring the power regulator using the method of any of claims 16 to 26.

In Example 28, the subject-matter of any of Examples 16 to 27 may optionally include that the taking the sequence of measurements is executed using a digital voltage monitor; wherein the method further comprises calibrating the digital voltage monitor before causing the deterministic load increase.

While the disclosure has been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

1. A power regulator monitoring circuit, comprising, on a chip:
a digital voltage monitor configured to:
take a sequence of measurements of an output voltage of a power regulator during a deterministic load increase to generate a sequence of digital output voltage measurement values; and
provide the sequence of digital output voltage measurement values;
a processing unit configured to receive and process the sequence of digital output voltage measurement values for determining at least one parameter of the power regulator that is indicative of a health state of the power regulator; and
a memory storing instructions to be executed by the processing unit and/or by a further processor that is connected to the power regulator monitoring circuit, wherein the instructions stored in the memory are arranged to cause a deterministic load increase of the power regulator when the instructions are run on the processing unit and/or on the further processor.

2. The power regulator monitoring circuit of claim 1, wherein:
the processing unit and/or the further processor, respectively, comprises a plurality of processor cores; and
the instructions are configured to be run on the plurality of processor cores in parallel to cause the deterministic load increase.

3. The power regulator monitoring circuit of claim 1, further comprising a further memory connected between the voltage monitor and the processing unit.

4. The power regulator monitoring circuit of claim 3, wherein the further memory comprises a volatile memory.

5. The power regulator monitoring circuit of claim 1, further comprising a hardware finite state machine (FSM) to control the digital voltage monitor and to trigger the deterministic load increase.

6. The power regulator monitoring circuit of claim 5, wherein the finite state machine (FSM) is further configured to register, synchronize and update states of the power regulator monitoring circuit using a common clock signal.

7. The power regulator monitoring circuit of claim 1, wherein:
the power regulator monitoring circuit is configured to:
compare the determined at least one parameter to at least one reference parameter; and
execute an action based on the result of the comparison, wherein the action includes optionally raising an alarm if the determined at least one parameter deviates by more than a predefined amount or percentage from the at least one reference parameter.

8. The power regulator monitoring circuit of claim 1, wherein the at least one parameter comprises at least one of a group of parameters, the group comprising one or more of:
a bandwidth of the power regulator;
an equivalent circuit parameter of the power regulator;
a time of recovery from a voltage droop event caused by the deterministic load increase; and
a noise value for the voltage signal.

9. The power regulator monitoring circuit of claim 1, wherein the processing further comprises a Fourier transform for determining a transfer function.

10. The power regulator monitoring circuit of claim 9, wherein the processing further comprises determining, from the transfer function, equivalent circuit parameters of the power regulator.

11. The power regulator monitoring circuit of claim 10, wherein:
the processing further comprises comparing the equivalent circuit parameters of the power regulator to reference equivalent circuit parameters of the power regulator;
the power regulator further comprises a feedback loop; and
the power regulator monitoring circuit is further configured, if a result of the comparison indicates that the determined equivalent circuit parameters differ from the reference equivalent circuit parameters of the power regulator by a correctable amount, to update feedback values to the feedback loop based on the determined equivalent circuit parameters.

12. The power regulator monitoring circuit of claim 1, wherein the processing unit further comprises a filter configured to filter out noise from the sequence of digital output voltage measurement values.

13. A power regulator system, comprising:
a power regulator; and
the power regulator monitoring circuit of claim 1.

14. The power regulator system of claim 13, wherein the power regulator is configured as one of a group of power regulators, the group comprising:
a Low Drop-Out (LDO) power regulator;
a DC-DC buck power regulator;
a DC-DC boost power regulator; and
a DC-DC buck-boost power regulator.

15. The power regulator system of claim 13, wherein the power regulator system is configured as a System-on-Chip (SoC).

16. A method of monitoring a power regulator, the method comprising:
causing a deterministic load increase of the power regulator;
taking a sequence of measurements of an output voltage of the power regulator during the deterministic load increase to generate a sequence of digital output voltage measurement values; and
processing the sequence of digital output voltage measurement values to determine at least one parameter of the power regulator that is indicative of a health state of the power regulator.

17. The method of claim 16, wherein the causing the load increase and the taking the sequence of measurements of the output voltage are synchronized through a common clock signal.

18. The method of claim 16, further comprising:
comparing the determined at least one parameter to at least one reference parameter; and
executing an action based on the result of the comparison, wherein the action includes optionally raising an alarm if the determined at least one parameter deviates by more than a predefined amount or percentage from the at least one reference parameter.

19. The method of claim 16, wherein the processing further comprises a Fourier transform for determining a transfer function.

20. The method of claim 19, wherein the processing further comprises determining, from the transfer function, equivalent circuit parameters of the power regulator.

21. The method of claim 20, wherein:
the processing further comprises comparing the equivalent circuit parameters of the power regulator to reference equivalent circuit parameters of the power regulator;
the power regulator comprises a feedback loop; and
the processing further comprises, if a result of the comparison indicates that the determined equivalent circuit parameters differ from the reference equivalent circuit parameters of the power regulator by a correctable amount, providing update feedback values to the feedback loop based on the determined equivalent circuit parameters.
